(19) United States
(12) Patent Application Publication
(10) Pub. No.: US 2012/0121800 A1
(43) Pub. Date: May 17, 2012

(54) METHOD OF MODIFYING SURFACE OF SUBSTRATE FOR INKJET PRINTING

(75) Inventors: Joong-hyuk Kim, Seoul (KR); Jae-woo Chung, Yongin-si (KR); Young-ki Hong, Anyang-si (KR)

(73) Assignee: SAMSUNG ELECTRONICS CO., LTD., Suwon-si (KR)

(21) Appl. No.: 13/094,292

(22) Filed: Apr. 26, 2011

(30) Foreign Application Priority Data
Nov. 15, 2010 (KR) 10-2010-0113487

(51) Int. Cl. B05D 5/12; H05K 3/12

(52) U.S. Cl. 427/98.5

(57) ABSTRACT

A method may include providing a surface modification inkjet head and a target inkjet head to be movable on a substrate, and forming a surface modification printed pattern by moving the surface modification inkjet head and ejecting surface modification ink onto the substrate. A target printed pattern may be formed by ejecting a target ink from the target inkjet head to the surface modification printed pattern and a metal wiring pattern may be formed on the substrate by removing the surface modification printed pattern.

### CROSS-REFERENCE TO RELATED APPLICATIONS

This application claims priority under 35 U.S.C. §119 to Korean Patent Application No. 10-2010-0113487, filed on Nov. 15, 2010, in the Korean Intellectual Property Office (KIPO), the disclosure of which is incorporated herein in its entirety by reference.

### BACKGROUND

1. Field

The present disclosure relates to methods of modifying a surface of a substrate for inkjet printing.

2. Description of the Related Art

Generally, an inkjet printing device is a device for printing a predetermined image by ejecting fine ink droplets to desired locations on a printing medium via nozzles of an inkjet head. Recently, inkjet printing devices are used not only for image printing, but also in various fields, such as flat panel displays including liquid crystal displays (LCDs) and organic light emitting devices (OLEDs), flexible displays including e-paper, printed electronics including metal wiring, organic thin-film transistors (OTFTs), biotechnology, bioscience, or the like.

In case of using an inkjet printing device for manufacturing displays or printed electronic circuits, one of the most important technical objectives is to prevent an open-circuit in wirings. Due to a difference between surface energies of ink ejected by an inkjet printing device and a substrate to be printed on, ink droplets ejected onto the substrate tend to bulge, and thus, ink may not be continuously printed.

### SUMMARY

Provided are methods of modifying the surface of a substrate for inkjet printing.

Additional aspects will be set forth in part in the description which follows and, in part, will be apparent from the description, or may be learned by practice of the example embodiments.

In accordance with an example embodiment of the invention, a method of modifying a surface of a substrate may include arranging an inkjet printing device on a substrate and forming a surface modification printed pattern on the substrate. In this example embodiment, the inkjet printing device may have a movable surface modification inkjet head and a movable target inkjet head and the surface modification printed pattern may be formed by moving the surface modification inkjet head across the substrate and ejecting surface modification ink from the surface modification ink jet head to the substrate.

In accordance with another example embodiment of the invention, a method of forming a metal wiring pattern may include providing a movable surface modification inkjet head and a movable target inkjet head on a substrate, forming a surface modification printed pattern on the substrate by moving the surface modification inkjet head and ejecting surface modification ink from the surface modification inkjet head onto the substrate, forming a target printed pattern on the surface modification printed pattern by moving the target inkjet head and ejecting target ink containing metal nanoparticles from the target inkjet head onto the surface modification printed pattern, and forming the metal wiring pattern on the substrate by removing the surface modification printed pattern.

According to an example embodiment of the present invention, a method of modifying a surface of a substrate may include providing a surface modification inkjet head and a target inkjet head to be movable on a substrate, and forming a surface modification printed pattern by moving the surface modification inkjet head and ejecting surface modification ink.

The surface modification printed pattern may be continuously formed on the substrate. The surface modification ink may contact the surface of the substrate at a contact angle from about 20° to about 50°.

The method may further include forming a target printed pattern by moving the target inkjet head and ejecting target ink. Here, a difference between surface energies of the surface modification ink and the substrate may be smaller than a difference between surface energies of the target ink and the substrate. The target printed pattern may be continuously formed on the surface modification printed pattern.

The method may further include forming the continuous target printed pattern on the substrate by removing the surface modification printed pattern. Here, the surface modification printed pattern may be removed as the surface modification ink is vaporized by natural drying or annealing.

The target printed pattern may include a metal wiring pattern. The substrate may be a hydrophilic substrate coated with a hydrophobic material, and the target ink may include a hydrophilic material. The surface modification ink may include a hydrophilic material.

The target ink may include metal nanoparticles. Here, the metal nanoparticles may include Au, Ag, or Cu.

According to another example embodiment of the present invention, a method of forming a metal wiring pattern may include providing a surface modification inkjet head and a target inkjet head to be movable on a substrate, forming a surface modification printed pattern by moving the surface modification inkjet head and ejecting surface modification ink, forming a target printed pattern on the surface modification printed pattern by moving the target inkjet head and ejecting target ink containing metal nanoparticles, and forming the continuous metal wiring pattern on the substrate by removing the surface modification printed pattern.

### BRIEF DESCRIPTION OF THE DRAWINGS

These and/or other aspects will become apparent and more readily appreciated from the following description of the example embodiments, taken in conjunction with the accompanying drawings of which:

FIG. 1 is a schematic diagram of an inkjet printing device for performing a method of modifying the surface of a substrate to be printed on, according to an example embodiment of the present invention; and

FIGS. 2 through 8 are diagrams for describing a method of modifying a surface of a substrate and a method of forming a continuous metal wiring pattern according to example embodiments of the present invention.

### DETAILED DESCRIPTION

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers that may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made in detail to example embodiments which are illustrated in the accompanying drawings, wherein like reference numerals refer to the like elements throughout. In this regard, the example embodiments may have different forms and should not be construed as being limited to the descriptions set forth herein. Accordingly, the example embodiments are merely described below, by referring to the figures, to explain aspects of the present description.

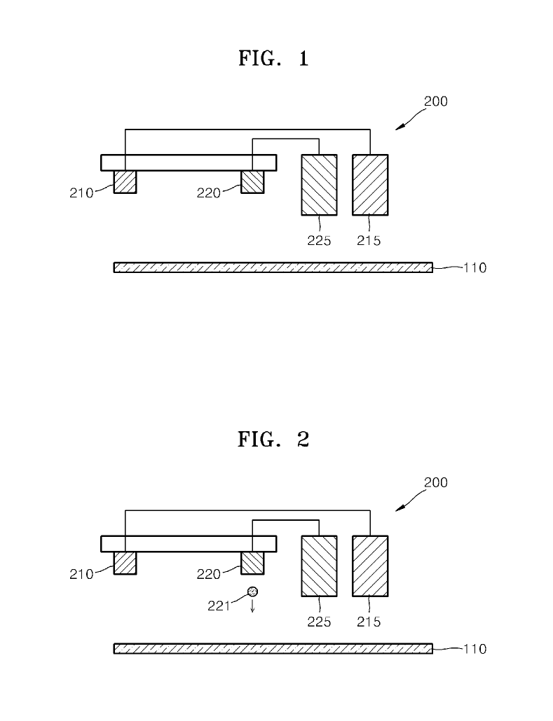

FIG. 1 is a schematic diagram of an inkjet printing device 200 for performing a method of modifying the surface of a substrate 110 to be printed on, according to an example embodiment of the present invention.

Referring to FIG. 1, the inkjet printing device 200 includes a surface modification inkjet head 220 and a target inkjet head 210. The surface modification inkjet head 220 and the target inkjet head 210 are configured to be movable on (or above) the substrate 110 to form printed patterns on a surface of the substrate 110. In example embodiments, the printed patterns may or may not be predetermined. The substrate 110 may be a hydrophilic substrate coated with a hydrophobic material. For example, the substrate 110 may be a glass substrate coated with octadecyltrichlorosilane (OTS), which is a hydrophobic material. However, the example embodiments are not limited thereto, and the substrate 110 may be formed of any of various materials.

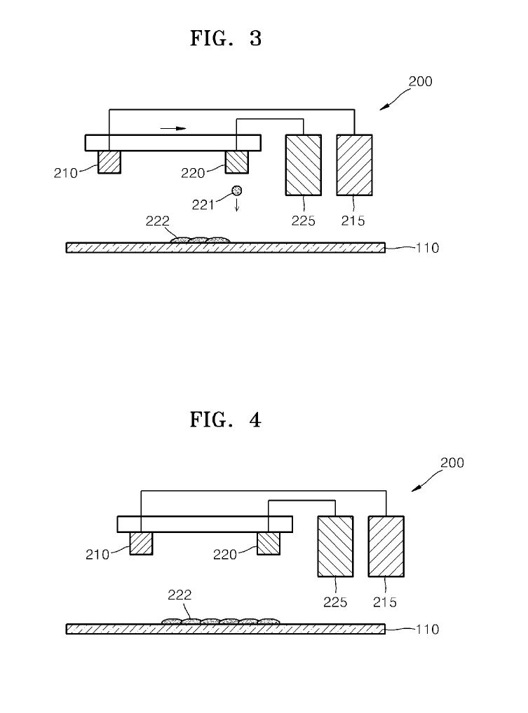

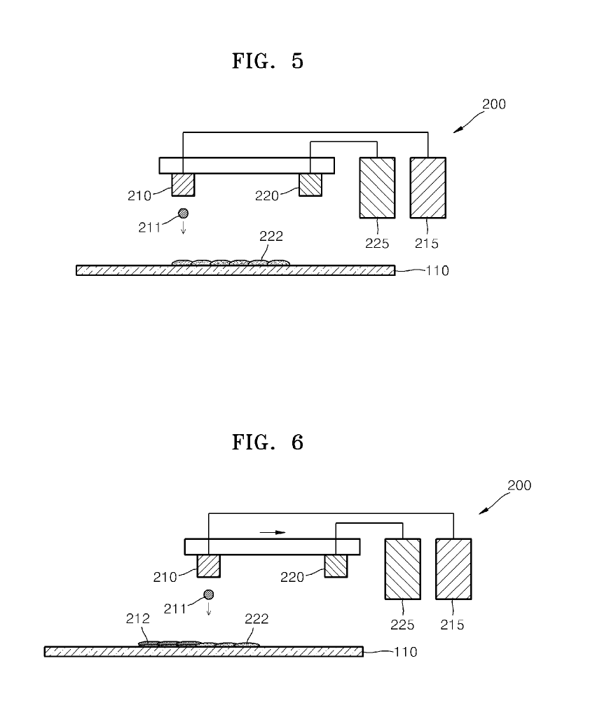

The surface modification inkjet head 220 forms a surface modification printed pattern (222 of FIG. 3) by moving surface modification inkjet head 220 and ejecting surface modification ink (221 of FIG. 2) onto the substrate 110. The surface modification inkjet head 220 forms the surface modification printed pattern 222 upon which a continuous target printed pattern 212 is formed. In this example embodiment, the surface modification inkjet head 220 is connected to a surface modification ink chamber 225, which supplies the surface modification ink 221. The target inkjet head 210 forms the target printed pattern (212 of FIG. 6) by moving and ejecting target ink (211 of FIG. 5) onto the substrate 110. The target inkjet head 210 may be connected to a target ink chamber 215, which supplies the target ink 211.

In case of forming a metal wiring pattern on the substrate 110, the target ink (211 of FIG. 5) may be formed of hydrophilic liquid containing metal nanoparticles. For example, the target ink 211 may be formed of water including Au, Ag, or Cu nanoparticles. Furthermore, the surface modification ink 221 may be formed of a material having affinity with the substrate 110. In other words, the surface modification ink 221 may be an ink having a material property for preventing an open-circuit by sufficiently wetting the surface of the substrate 110 according to a surface property of the substrate 110. In detail, the surface modification ink 221 may be formed of a material, where a difference between surface energies of the surface modification ink 221 and the substrate 110 is smaller than a difference between surface energies of the target ink 211 and the substrate 110. The surface modification ink 221 may be formed of a hydrophilic material. For example, the surface modification ink 221 may be formed of n-tetradecane. However, this is merely an example, and the surface modification ink 221 may be formed of any of various other materials.

For example, if a glass substrate coated with OTS is used as the substrate 110 and water including Ag nanoparticles is used as the target ink 211, a contact angle at which the target ink 211 contacts the surface of the substrate 110 is about 100°. However, a contact angle at which the target ink 211 contacts the surface of the substrate 110 must be from about 20° to about 50°, such that the target ink 211 forms the continuous target printed pattern (212 of FIG. 6) without bulging. Therefore, the target ink 211 bulges on the substrate 110 at a relatively large contact angle around 100°, and thus there may be discontinuities in a metal wiring pattern. According to the present example embodiment, to prevent or reduce such discontinuities, the surface modification ink 221 is printed on the substrate 110 first, and then the target ink 211 is printed thereon. Therefore, the continuous target printed pattern 212, that is, a continuous metal wiring pattern, may be formed.

For example, in case of using n-tetradecane as the surface modification ink 221, a contact angle at which the surface modification ink 221 contacts the surface of the substrate 110 is about 25°, and thus the surface modification ink 221 may form the continuous surface modification printed pattern 222 on the substrate 110 without bulging. On the other hand, if a contact angle at which the surface modification ink 221 contacts the surface of the substrate 110 is not proper, the surface modification ink 221 may spread on the substrate 110. Next, when the target ink 211 is printed on the surface modification printed pattern 222, a contact angle at which the target ink 211 contacts the surface modification printed pattern 222 is smaller than a contact angle at which the target ink 211 contacts the surface of the substrate 110. As a result, wetting of the target ink 211 on the surface modification printed pattern 222 increases, and thus, the continuous target printed pattern 212, that is, a continuous metal wiring pattern, may be formed on the surface modification printed pattern 222. Furthermore, even if the target ink 211 is ejected on a portion of the substrate 110 outside the surface modification printed pattern 222, the target ink 211 moves onto the surface modification printed pattern 222 due to a difference between surface energies of the target ink 211 and the substrate 110, and thus, the continuous target printed pattern 212 may be formed.

Hereinafter, a method of modifying a surface of the substrate 110 by using the inkjet printing device 200 and a method of forming the continuous target printed pattern 212, that is, a continuous metal wiring pattern by using the inkjet printing device 200 will be described. FIGS. 2 through 8 are diagrams for describing a method of modifying a surface of a substrate and a method of forming a continuous metal wiring pattern according to an example embodiment of the present invention.

Referring to FIG. 2, the inkjet printing device 200, including the surface modification inkjet head 220 and the target inkjet head 210, is prepared and arranged on or over the substrate 110. The surface modification inkjet head 220 and the target inkjet head 210 may be movable on or over the substrate 110. The surface modification inkjet head 220 and the target inkjet head 210 may be configured to move independently or together. The surface modification inkjet head 220 may be connected to the surface modification ink chamber 225 which supplies the surface modification ink 221, whereas the target inkjet head 210 may be connected to the target ink chamber 215 which supplies the target ink 211. The substrate 110 may be a hydrophilic substrate coated with a hydrophobic material. However, example embodiments of the present invention are not limited thereto. In case of forming a metal wiring pattern, the target ink 211 may be formed of hydrophilic liquid containing metal nanoparticles. For example, the target ink 211 may be formed of water through which Au, Ag, or Cu nanoparticles are distributed. In this case, the target ink 211 may have a relatively large contact angle around 100° with respect to the substrate 110.

The surface modification ink 221 may be an ink having a material property for preventing an open-circuit by sufficiently wetting the surface of the substrate 110 according to a surface property of the substrate 110. In detail, the surface modification ink 221 may be formed of a material, wherein a difference between surface energies of the surface modification ink 221 and the substrate 110 is smaller than a difference between surface energies of the target ink 211 and the substrate 110. The surface modification ink 221 may contact the surface of the substrate 110 at a contact angle from about 20° to about 50°. The surface modification ink 221 may be formed of a hydrophilic material, but example embodiments of the present invention are not limited thereto. Next, the surface modification inkjet head 220 is located on or over a printing starting point on the substrate 110 and the surface modification ink 221 is ejected from the surface modification inkjet head 220.

Next, as shown in FIG. 3, as the surface modification inkjet head 220 is moved, the surface modification printed pattern 222 begins to be formed on the substrate 110. When the surface modification ink 221 is completely ejected, the surface modification printed pattern 222 having a shape is completely formed on the substrate 110 as shown in FIG. 4. In example embodiments, the surface modification printed patterns 222 may or may not have a predetermined shape. In this example embodiment, since the surface modification ink 221 contacts the surface of the substrate 110 at a relatively small contact angle, that is, a contact angle from about 20° to about 50°, the surface modification printed pattern 222 may be continuously formed on the substrate 110 without a discontinuity. Accordingly, the surface of the substrate 110 is first modified by forming the surface modification printed pattern 222, and the continuous target printed pattern 212, that is, a continuous metal wiring pattern, is formed thereon as described below.

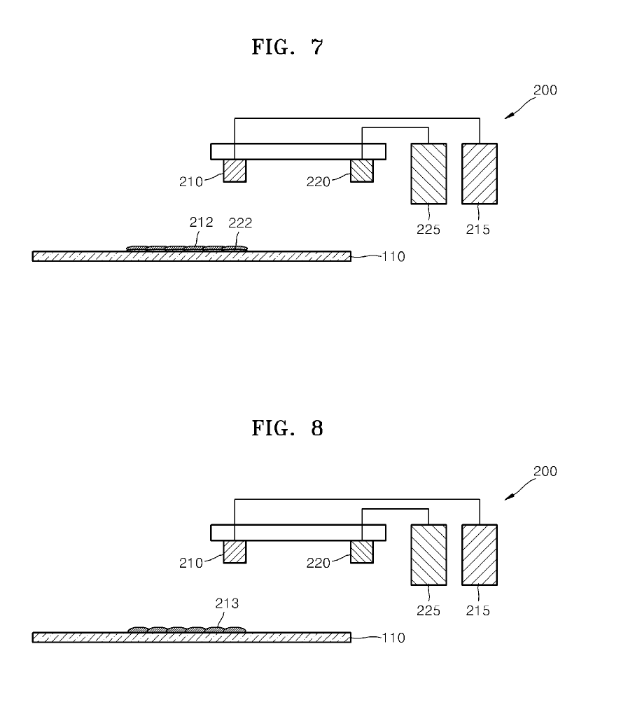

Referring to FIG. 5, the target inkjet head 210 is located pointing an area where the formation of the surface modification printed pattern 222 on the substrate 110 has begun and the target ink 211 is ejected from the target inkjet head 210. Next, as shown in FIG. 6, as the target inkjet head 210 is moved along the surface modification printed pattern 222, the target printed pattern 212 (a metal wiring pattern) begins to be formed on the surface modification printed pattern 222. When the target ink 211 is completely ejected, the target printed pattern 212 (the metal wiring pattern) is completely formed on the surface modification printed pattern 222 as shown in FIG. 7. Since a difference between surface energies of the target ink 211 and the surface modification ink 221 is smaller than a difference between surface energies of the target ink 211 and the substrate 110, the target printed pattern 212 (the metal wiring pattern) may be continuously formed on the surface modification printed pattern 222 without a discontinuity. In example embodiments, the target ink 211 may be ejected on a portion of the substrate 110 outside the surface modification printed pattern 222. In this case, the target ink 211 moves onto the surface modification printed pattern 222 due to a difference between surface energies of the target ink 211 and the substrate 110, and thus, the continuous target printed pattern 212 may be formed.

Next, as shown in FIG. 8, when the surface modification printed pattern 222 is removed, the continuous target printed pattern 212 (the metal wiring pattern) is formed on the substrate 110. For example, when the surface modification printed pattern 222 and the target printed pattern 212 (the metal wiring pattern) are dried, the surface modification printed pattern 222 is removed through vaporization. Furthermore, a solvent (e.g., water) in the target printed pattern 212 is also removed through vaporization. Here, the surface modification printed pattern 222 and the target printed pattern 212 (the metal wiring pattern) may be dried naturally or via annealing. As a result, the target printed pattern 212 (the metal wiring pattern) containing only metal nanoparticles may be continuously formed on the substrate 110 without a discontinuity. In the above descriptions, the case of forming a surface modification printed pattern on a substrate and forming a target printed pattern on the surface modification printed pattern has been presented. However, the surface modification inkjet head 220 and the target inkjet head 210 may simultaneously move to form the target printed pattern 212 while the surface modification printed pattern is being formed.

As described above, according to the one or more of the above example embodiments of the present invention, a continuous metal wiring pattern may be formed by printing a surface modification ink on a substrate and printing a target ink thereon.

It should be understood that the example embodiments described herein should be considered in a descriptive sense only and not for purposes of limitation. Descriptions of features or aspects within example embodiments should typically be considered as available for other similar features or aspects in other embodiments.

What is claimed is:

1. A method of modifying a surface of a substrate, the method comprising:
arranging an inkjet printing device on a substrate, the inkjet printing device having a movable surface modification inkjet head and a movable target inkjet head; and
forming a surface modification printed pattern on the substrate by moving the surface modification inkjet head across the substrate and ejecting surface modification ink from the surface modification ink jet head to the substrate.

2. The method of claim 1, wherein the surface modification inkjet head is moved to continuously form the surface modification printed pattern on the substrate.

3. The method of claim 1, wherein surface modification ink contacts the surface of the substrate at a contact angle from about 20° to about 50°.

4. The method of claim 2, further comprising:
forming a target printed pattern on the surface modification printed pattern by moving the target inkjet head across the surface modification printed pattern and ejecting target ink from the target inkjet head onto the surface modification printed pattern.

5. The method of claim 4, wherein a difference between surface energies of the surface modification ink and the substrate is smaller than a difference between surface energies of the target ink and the substrate.

6. The method of claim 4, wherein the target inkjet head is moved to continuously form the target printed pattern on the surface modification printed pattern.

7. The method of claim 4, further comprising:
forming the continuous target printed pattern on the substrate by removing the surface modification printed pattern.

8. The method of claim 7, wherein removing the surface modification printed pattern includes vaporizing the surface modification ink by at least one of natural drying and annealing.

9. The method of claim 7, wherein the target printed pattern comprises a metal wiring pattern.

10. The method of claim 4, wherein the substrate is a hydrophilic substrate coated with a hydrophobic material, and the target ink comprises a hydrophilic material.

11. The method of claim 10, wherein the surface modification ink comprises a hydrophilic material.

12. The method of claim 10, wherein the target ink comprises metal nanoparticles.

13. The method of claim 12, wherein the metal nanoparticles comprise at least one of Au, Ag, and Cu.

14. A method of forming a metal wiring pattern, the method comprising:
providing a movable surface modification inkjet head and a movable target inkjet head on a substrate;
forming a surface modification printed pattern on the substrate by moving the surface modification inkjet head and ejecting surface modification ink from the surface modification inkjet head onto the substrate;
forming a target printed pattern on the surface modification printed pattern by moving the target inkjet head and ejecting target ink containing metal nanoparticles from the target inkjet head onto the surface modification printed pattern; and
forming the metal wiring pattern on the substrate by removing the surface modification printed pattern.

15. The method of claim 14, wherein a difference between surface energies of the surface modification ink and the substrate is smaller than a difference between surface energies of the target ink and the substrate.
